(19) United States
(12) Patent Application Publication
(10) Pub. No.: US 2025/0357725 A1
(43) Pub. Date: Nov. 20, 2025

(54) SEMICONDUCTOR OPTICAL DEVICE AND OPTICAL INTEGRATED DEVICE

(71) Applicant: FURUKAWA ELECTRIC CO., LTD., Tokyo (JP)

(72) Inventors: Masahiro YOSHIDA, Tokyo (JP); Kazuaki KIYOTA, Tokyo (JP)

(73) Assignee: FURUKAWA ELECTRIC CO., LTD., Tokyo (JP)

(21) Appl. No.: 19/284,801

(22) Filed: Jul. 30, 2025

Related U.S. Application Data
(63) Continuation of application No. PCT/JP2024/003821, filed on Feb. 6, 2024.

(30) Foreign Application Priority Data
Feb. 7, 2023 (JP) 2023-017089

(51) Int. Cl. H01S 5/042; H01S 5/10; H01S 5/20

(52) U.S. Cl. CPC H01S 5/04256; H01S 5/101; H01S 5/2018

(57) ABSTRACT

A semiconductor optical device includes: a substrate expanding while intersecting with a first direction; a plurality of waveguide structures each of which includes a first cladding layer, a core layer, and a second cladding layer that are layered in the first direction, the plurality of waveguide structures extending in a second direction that intersects with the first direction and guiding lights in the second direction or opposite direction to the second direction, and being disposed away from each other in a third direction that intersects with the first direction and the second direction; and a first electrode disposed on an opposite side of the substrate with respect to the waveguide structures, and including a first portion and a second portion having a thickness thicker than a thickness of the first portion in the first direction.

This application is a continuation of International Application No. PCT/JP2024/003821, filed on Feb. 6, 2024 which claims the benefit of priority of the prior Japanese Patent Application No. 2023-017089, filed on Feb. 7, 2023, the entire contents of which are incorporated herein by reference.

### BACKGROUND

The present intention relates to a semiconductor optical device and an optical integrated device.

In the related art, an optical integrated device is known in which a semiconductor optical device, such as a semiconductor laser device or a semiconductor optical amplifier, and a part including a waveguide (hereinafter, that part is referred to as an optical function device) are included in an integrated manner (for example, refer to Japanese Patent Application Laid-open No. 2017-92262).

### SUMMARY

A semiconductor optical device of the abovementioned type includes a semiconductor layer constituting waveguide structures and includes a metal layer constituting electrodes. Regarding such a semiconductor optical device, if there is a significant temperature difference between the time of manufacturing and at the time of operation, due to the difference in the coefficient of thermal expansion of the semiconductor layer and the coefficient of thermal expansion of the metal layer, there occurs a difference in the extent of heat contraction depending on the position. Hence, there arises a risk that the semiconductor optical device undergoes deformation with respect to the intended shape. In the following explanation, such deformation is simply referred to as thermal deformation. Examples of thermal deformation include warpage of the semiconductor optical device in the form of a protrusion or a depression in the layering direction of the waveguide structure.

In a semiconductor optical device that includes only a single waveguide, even if thermal deformation occurs as explained above, as a result of performing positioning between the concerned waveguide and the waveguide of another optical device that is optically connected (hereinafter, simply referred to as the corresponding waveguide), it becomes possible to hold down the optical loss between the concerned waveguide and the corresponding waveguide. However, in a semiconductor optical device that includes a plurality of waveguides, when thermal deformation occurs, the relative positional relationship among the waveguides changes, and it becomes difficult to hold down the optical loss between each concerned waveguide and its corresponding waveguide.

Such thermal deformation can be held down by reducing the volume of the metal layer constituting electrodes. However, if the volume of the metal layer is reduced, there is a risk of facing the following problem. That is, the area of cross-section of the electrodes decreases and the electrical resistance increases. Moreover, the surface area of the electrodes becomes smaller and thermal dissipation undergoes a decline. For that reason, it becomes difficult to achieve the intended performance.

There is a need for a semiconductor optical device and an optical integrated device in a new and improved form so as to enable holding down thermal deformation and at the same time enable holding down an increase in the electrical resistance in the electrodes and holding down a decline in thermal dissipation attributed to the electrodes.

According to one aspect of the present disclosure, there is provided a semiconductor optical device including: a substrate expanding while intersecting with a first direction; a plurality of waveguide structures each of which includes a first cladding layer, a core layer, and a second cladding layer that are layered in the first direction, the plurality of waveguide structures extending in a second direction that intersects with the first direction and guiding lights in the second direction or opposite direction to the second direction, and being disposed away from each other in a third direction that intersects with the first direction and the second direction; and a first electrode disposed on an opposite side of the substrate with respect to the waveguide structures, and including a first portion and a second portion having a thickness thicker than a thickness of the first portion in the first direction.

### BRIEF DESCRIPTION OF THE DRAWINGS

FIG. 1 is an illustrative and schematic cross-sectional view of a semiconductor optical device according to a first embodiment;

FIG. 2 is an illustrative and schematic planar view of the semiconductor optical device according to the first embodiment;

FIG. 3 is an illustrative and schematic planar view of a semiconductor optical device according to a second embodiment;

FIG. 4 is an illustrative and schematic planar view of a semiconductor optical device according to a third embodiment;

FIG. 5 is a V-V cross-sectional view of FIG. 4;

FIG. 6 is an illustrative and schematic planar view of a semiconductor optical device according to a fourth embodiment;

FIG. 7 is an illustrative and schematic planar view of a semiconductor optical device according to a fifth embodiment;

FIG. 8 is a VIII-VIII cross-sectional view of FIG. 7;

FIG. 9 is an illustrative and schematic cross-sectional view of a semiconductor optical device according to a sixth embodiment;

FIG. 10 is an illustrative and schematic planar view of the semiconductor optical device according to the sixth embodiment; and

FIG. 11 is an illustrative and schematic planar view of an optical integrated device, which includes a semiconductor optical device and an optical function device, according to a seventh embodiment.

### DETAILED DESCRIPTION

Exemplary embodiments are described below. The configurations explained in the embodiments described below as well as the actions and the results (effects) attributed to the configurations are only exemplary. Thus, the present disclosure can be implemented also using some different configuration than the configurations disclosed in the embodiments described below. Meanwhile, according to the present disclosure, it becomes possible to achieve at least one of various effects (including secondary effects) that are attributed to the configurations.

The embodiments below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating among the directions and the portions. Thus, the ordinal numbers neither indicate the priority or the sequencing nor restrict the count.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. In the following explanation, the X direction can be referred to as the longitudinal direction or the direction of extension. The Y direction can be referred to as the short direction or the width direction. The Z direction can be referred to as the layering direction or the height direction.

Meanwhile, the drawings are schematic diagrams intended for use in the explanation. Thus, in the drawings, the scale and the ratio does not necessarily match with the actual objects.

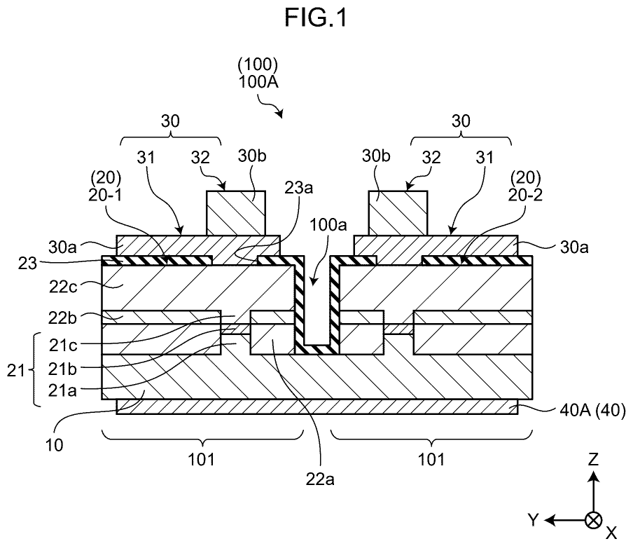

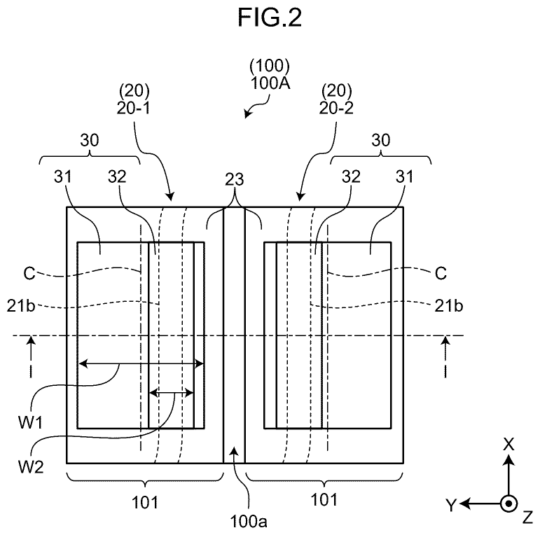

FIG. 1 is a cross-sectional view of a semiconductor optical device 100A (100) according to a first embodiment. FIG. 2 is a planar view of the semiconductor optical device 100A (100). Herein, FIG. 1 is an I-I cross-sectional view of FIG. 2.

As illustrated in FIGS. 1 and 2, the semiconductor optical device 100A includes a substrate 10, two waveguide structures 20 (20-1 and 20-2), electrodes 30, and an electrode 40A (40). The electrode 40A, the substrate 10, the waveguide structure 20-1, an insulation layer 23, and one electrode 30 constitute a function unit 101.

Similarly, the electrode 40A, the substrate 10, the waveguide structure 20-2, another insulation layer 23, and the other electrode 30 constitute another function unit 101. Thus, the substrate 10 and the electrode 40A are used in common in the function units 101; while the waveguide structures 20, the insulation layers 23, and the electrodes 30 are separately disposed in the function units 101. Since both function units 101 have substantially same structures and substantially same functions, the following explanation is given only about one of the function units 101 (the function unit 101 illustrated on the left side in FIG. 1). Meanwhile, a slit 100a is formed in between the two function units 101.

The substrate 10 has a substantially constant thickness in the Z direction and expands while intersecting with the Z direction. The substrate 10 is made of, for example, n-InP. The layers constituting the waveguide structures 20, the insulation layers 23, and the electrodes 30 are layered on the substrate 10 in the Z direction. The Z direction can be referred to as the layering direction, the thickness direction, or the height direction. The Z direction represents an example of a first direction.

The electrode 40 is disposed on that surface of the substrate 10 which is on the opposite side of the Z direction. The electrode 40 is an N-side electrode and is separated from a core layer 21b in the opposite direction to the Z direction. The electrode 40 has, for example, a layering structure including AuGe, Ni, and Au. The electrode 40 represents an example of a second electrode.

On that surface of the substrate 10 which is on the opposite side of the electrode 40, a mesa 21 is formed that includes a cladding layer 21a, the core layer 21b, and a cladding layer 21c. The cladding layer 21a, the core layer 21b, and the cladding layer 21c are layered in that order on the substrate 10 in the Z direction. The mesa 21 extends in the X direction with a substantially constant width in the Y direction and a substantially constant height in the Z direction.

The cladding layer 21a is layered on the substrate 10. The cladding layer 21a is made of, for example, n-InP. The core layer 21b is layered on the cladding layer 21a. The core layer 21b has, for example, a layering structure including n-InGaAsP. The cladding layer 21c is layered on the core layer 21b. The cladding layer 21c is made of, for example, p-InP. The cladding layer 21a represents an example of a first cladding layer, and the cladding layer 21c represents an example of a second cladding layer.

The mesa 21 is enclosed by current blocking layers 22a and 22b that are adjacent to the mesa 21 in the Y direction and the opposite direction to the Y direction; and is enclosed by a cladding layer 22c that is adjacent to the mesa 21 in the Z direction. The current blocking layer 22a is made of, for example, p-InP; and the current blocking layer 22b is made of, for example, n-InP. The cladding layer 22c is made of, for example, p-InP. The cladding layer 22c represents an example of a second cladding layer.

Each waveguide structure 20 that includes the cladding layer 21a, the core layer 21b, the cladding layer 21c, the current blocking layers 22a and 22b, and the cladding layer 22c is covered by the insulation layer 23. On the insulation layer 23, an opening 23a is formed at the position that overlaps with the mesa 21 in the Z direction. Meanwhile, the configuration of the waveguide structures 20 and the insulation layers 23 is not limited to the example explained above.

The two waveguide structures 20 extend in the X direction and guide the light in the X direction or in the opposite direction to the X direction. Moreover, the two waveguide structures 20 (20-1 and 20-2) are separated from each other in the Y direction, and are arranged in the Y direction across the slit 100a. The X direction represents an example of a second direction, and the Y direction represents an example of a third direction.

On each waveguide structure 20, the electrode 30 that is made of an electrical conductor is disposed on the opposite side of the substrate 10 with respect to the cladding layer 22c. The electrode 30 is a P-side electrode and is separated from the active core layer 21b in the Z direction. The electrode 30 includes a first layer 30a and a second layer 30b that is layered on the first layer 30a. The first layer 30a makes contact with the cladding layer 22c via the opening 23a formed on the insulation layer 23. The first layer 30a can be referred to as a thin film layer, and the second layer 30b can be referred to as a thick film layer. Each electrode 30 represents an example of a first electrode. Meanwhile, the electrodes 30 and 40 constitute an electrode pair.

Each function unit 101 having the abovementioned configuration can function as, for example, a semiconductor optical amplifier. The semiconductor optical amplifier performs optical amplification of the light input from one end of the core layer 21b, and outputs the optically-amplified light from the other end of the core layer 21b. Thus, the semiconductor optical device 100A is configured as a semiconductor optical amplifier array. In that case, the core layer 21b of the function unit 101 is referred to as an active layer, and represents an example of an active waveguide.

As illustrated in FIG. 1, the second layer 30b covers some portion of the first layer 30a. Thus, the electrode 30 includes a first portion 31 that is made of only the first layer 30a, and a second portion 32 that is made of the first layer 30a and the second layer 30b and accordingly has a greater thickness than the thickness of the first portion 31. If the electrode 30 is made of only the second portion 32 having a greater thickness, there is a risk of an increase in the thermal deformation. On the other hand, if the electrode 30 is made of only the first portion 31, there is a risk that the area of cross-section of the electrode 30 decreases thereby leading to an increase in the electrical resistance, and that the surface area of the electrode 30 decreases thereby leading to a decline in thermal dissipation. In that regard, according to the first embodiment, since the electrode 30 includes the first portion 31 having a relatively smaller thickness and the second portion 32 having a relatively greater thickness, it becomes possible to hold down the thermal deformation and at the same time to hold down an increase in the electrical resistance or a decline in thermal dissipation.

Meanwhile, as is the case in the first embodiment, when a plurality of waveguide structures 20 is separated in the Y direction, if thermal deformation results in a change in the relative positions of the core layers 21b of the two waveguide structures 20, it has an impact on the decline in the efficiency of optical coupling between the core layers 21b and the waveguides corresponding to the core layers 21b. Regarding the change in the relative positions of a plurality of core layers 21b, the thermal deformation in the deformation mode in which the position of each layer in the Z direction goes on changing toward the Y direction (hereinafter, referred to as a second deformation mode) has a greater impact than the impact of the thermal deformation in the deformation mode in which the position of each layer in the Z direction goes on changing toward the X direction (hereinafter, referred to as a first deformation mode). In that regard, in the first embodiment, as illustrated in FIG. 2, the electrodes 30 extend in the X direction across a width W1, and the second portions 32 extend in the X direction across a width W2 that is smaller than the width W1. In other words, the first portions 31 as well as the second portions 32 extend in the X direction, and are lined up in the Y direction. If the second portions 32 extend in the Y direction, due to the drop in the temperature at the time of operation as compared to the temperature at the time of manufacturing, the second portions 32 contract over a longer distance in the Y direction. Hence, in the semiconductor optical device 100, the deformation in the second deformation mode becomes greater than the deformation in the first deformation mode. In that regard, in the first embodiment, the second portions 32 extend in the X direction, so that the deformation in the second deformation mode can be reduced. Hence, while ensuring the required electrical conductivity and the required thermal dissipation in the electrodes 30, it becomes possible to hold down the change in the relative positions of the core layers 21b. In turn, it becomes possible to hold down the decline in the efficiency of optical coupling between the core layers 21b and the waveguides corresponding to the core layers 21b. Meanwhile, the width W1 represents an example of a first width, and the width W2 represents an example of a second width.

Moreover, as illustrated in FIG. 2, in the first embodiment, the second portions 32 extend in the X direction at the positions overlapping with the corresponding core layers 21b in the Z direction. As a result, as compared to the case in which the electrodes 30 are placed at positions that do not overlap with the corresponding core layers 21b in the Z direction, it becomes possible to efficiently supply the electrical power from the electrodes 30 to the corresponding core layers 21b.

Furthermore, as illustrated in FIG. 2, in the first embodiment, when viewed from the opposite direction to the Z direction, with respect to a central line C positioned in the center of each electrode 30 in the X direction, the corresponding second portion 32 is misaligned in the Y direction or the opposite direction to the Y direction. When the end surface of the first portion 31 in the Z direction is used as the region to which a wiring (not illustrated) is bonded using a wire bonding or is used as the region to which a probe is touched for confirming the height, it is desirable to secure a wider portion as the first portion 31. In that regard, in the first embodiment, since the second portion 32 is placed at a position shifted in the Y direction with respect to the central line C of the electrode 30, as compared to the case in which the second portion 32 is placed at a position overlapping with the central line C of the electrode 30, the end surface of at least one first portion 31 in the Z direction can be secured to be wider.

As explained above, each electrode 30 includes the first layer 30a and the second layer 30b. The first layer 30a partially constitutes the first portion 31 and the second portion 32, and the second layer 30b constitutes that part of the second portion 32 which is on the opposite side of the waveguide structure 20 with respect to the first layer 30a. According to the first embodiment, each electrode 30 that includes the first portion 31 and the second portion 32 having different thicknesses can be configured according to a relatively simpler process.

As explained above, according to the first embodiment, it becomes possible to obtain the semiconductor optical device 100 in a new and improved form that, for example, enables holding down thermal deformation and at the same time enables holding down an increase in the electrical resistance in the electrodes 30 and holding down a decline in thermal dissipation attributed to the electrodes 30.

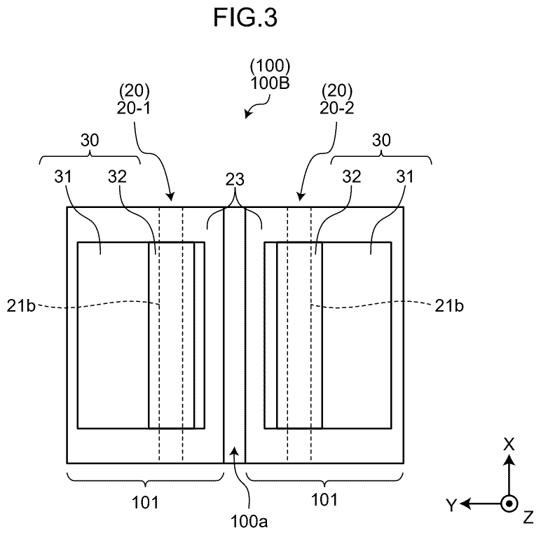

FIG. 3 is a planar view of a semiconductor optical device 100B (100) according to a second embodiment. In the second embodiment, although the configuration of the function units 101 is different than the configuration according to the first embodiment, each function unit 101 operates as a semiconductor optical device such as a semiconductor laser that includes the waveguide structure 20, one electrode 30, and the electrode 40 (see FIG. 1) in an identical manner to the first embodiment. The semiconductor optical device outputs a light from one end of the core layer 21b. That is, the semiconductor optical device 100B according to the second embodiment is configured as a semiconductor light-emitting device array. When semiconductor lasers are used as the semiconductor light-emitting devices, each function unit 101 includes a reflective coating constituting a laser resonator. On the other hand, when DFB semiconductor lasers are used as the semiconductor optical devices, each function unit 101 further includes a diffraction grating layer for defining laser emission wavelengths. In the second embodiment, the electrodes 30 have an identical configuration to the configuration according to the first embodiment. Hence, in the second embodiment too, it becomes possible to achieve identical effects to the effects achieved according to the first embodiment.

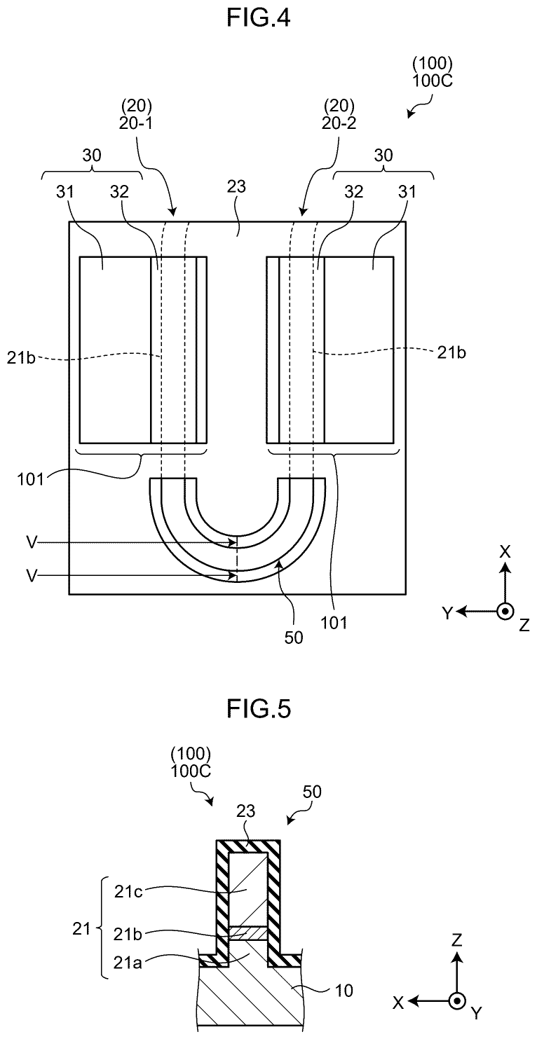

FIG. 4 is a planar view of a semiconductor optical device 100C (100) according to a third embodiment. FIG. 5 is a V-V cross-sectional view of FIG. 4. In the third embodiment, the two function units 101 have an identical configuration to the configuration according to the first embodiment and operate as semiconductor optical amplifiers. Moreover, the waveguide structures 20 of the two function units 101 are optically connected via a folded waveguide structure 50 that includes the core layer 21b functioning as a passive waveguide. As illustrated in FIG. 5, the folded waveguide structure 50 has a high-mesa structure. With such a structure, the semiconductor optical device 100C entirely functions as a semiconductor optical amplifier. The semiconductor optical amplifier performs optical amplification of the light input from one end of the core layer 21b of one of the function units 101, and outputs the optically-amplified light from one end of the core layer 21b of the other function unit 101. In the third embodiment, the electrodes 30 have an identical configuration to the configuration according to the first embodiment. Hence, according to the third embodiment too, it becomes possible to achieve identical effects to the effects achieved according to the first embodiment.

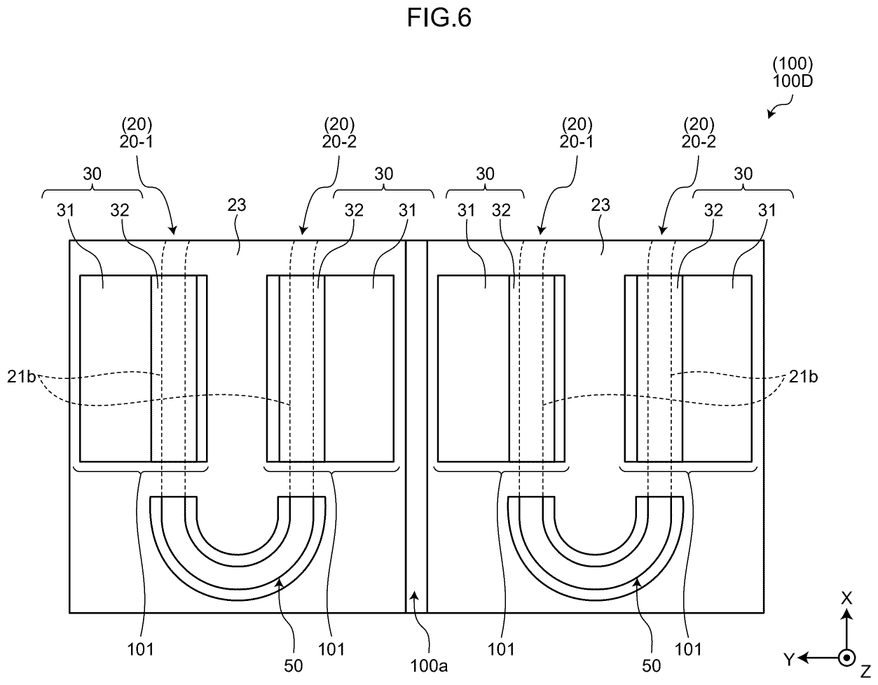

FIG. 6 is a planar view of a semiconductor optical device 100D (100) according to a fourth embodiment. In the fourth embodiment, semiconductor optical amplifiers identical to the third embodiment are lined up in the Y direction across the slit 100a. That is, the semiconductor optical device 100D according to the fourth embodiment is configured as a semiconductor optical amplifier array. In the fourth embodiment too, the electrodes 30 have an identical configuration to the configuration according to the first embodiment. Hence, according to the fourth embodiment too, it becomes possible to achieve identical effects to the effects achieved according to the first embodiment.

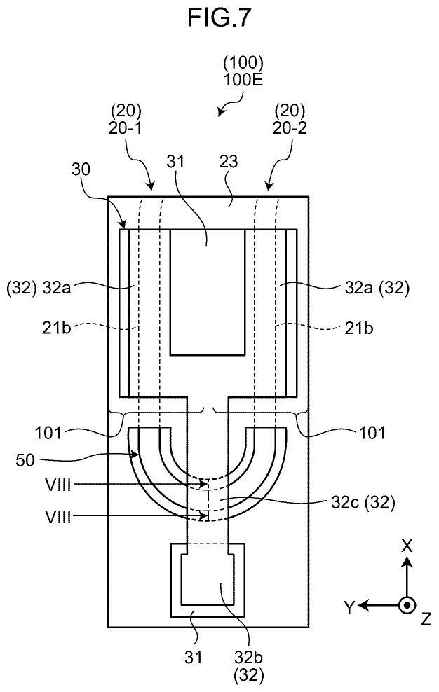

FIG. 7 is a planar view of a semiconductor optical device 100E (100) according to a fifth embodiment. The semiconductor optical device 100E according to the fifth embodiment includes the two function units 101 and the folded waveguide structure 50 identical to the semiconductor optical device 100C according to the third embodiment, and operates in an identical manner to the semiconductor optical device 100C. However, in the fifth embodiment, the electrodes 30 have a different configuration than the configuration according to the third embodiment.

More particularly, the second portion 32 includes action portions 32a, a pad portion 32b, and an extended portion 32c. The action portions 32a overlap with the core layer 21b in the Z direction in the function units 101, and supply electrodes to the mesas 21. The pad portion 32b is disposed on the opposite side of the two function units 101 with respect to the folded waveguide structure 50. To the pad portion 32b is bonded a power supply member such as a bonding wire. The extended portion 32c extends in the X direction in between the action portions 32a and the pad portion 32b. The pad portion 32b and the extended portion 32c are used in common for a plurality of action portions 32a.

In the fifth embodiment, the second portion 32 extends in the X direction for a longer distance than the first portion 31. According to the fifth embodiment, in an identical manner to the first embodiment, while ensuring the required electrical conductivity and the required thermal dissipation in the electrodes 30, it becomes possible to further reduce the deformation in the second deformation mode in which the position of each layer in the Z direction goes on changing toward the Y direction. Hence, it becomes possible to hold down the change in the relative positions of the core layers 21b. In turn, it becomes possible to hold down the decline in the efficiency of optical coupling between the core layers 21b and the waveguides corresponding to the core layers 21b.

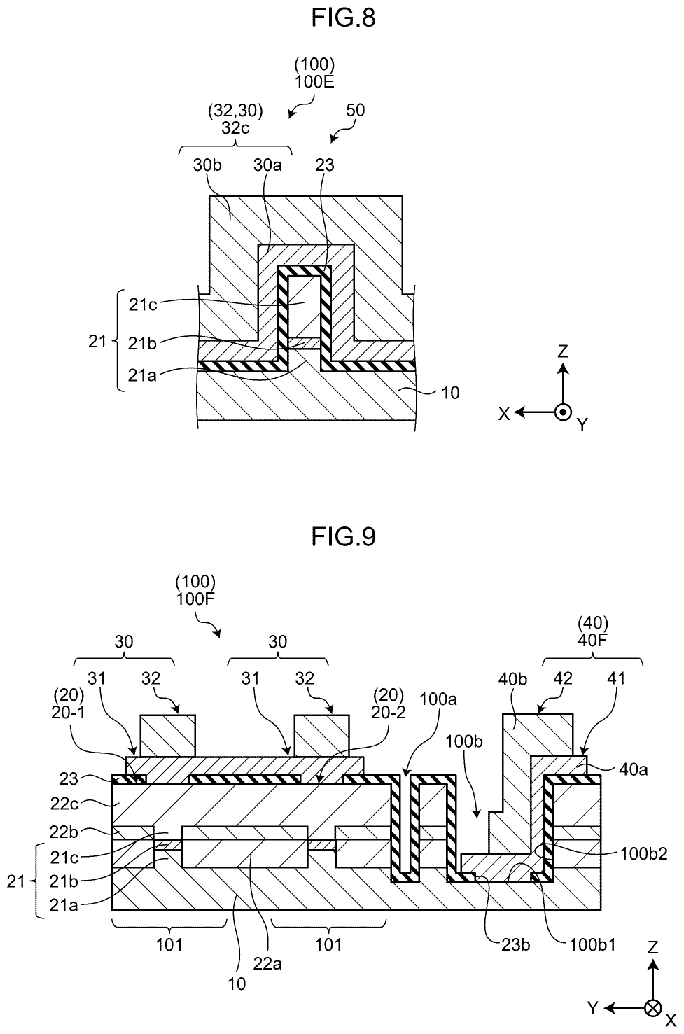

FIG. 8 is a VIII-VIII cross-sectional view of FIG. 7. As illustrated in FIG. 8, in the fifth embodiment, the level difference of the folded waveguide structure 50, which has a high-mesa structure, is crossed by (the extended portion 32c of) the second portion 32 that includes the first layer 30a and the second layer 30b and that has a greater thickness than the thickness of the first portion 31. With such a configuration, it becomes possible to prevent the disconnection of the electrode 30 at the crossing position, and to hold down an increase in the electrical resistance.

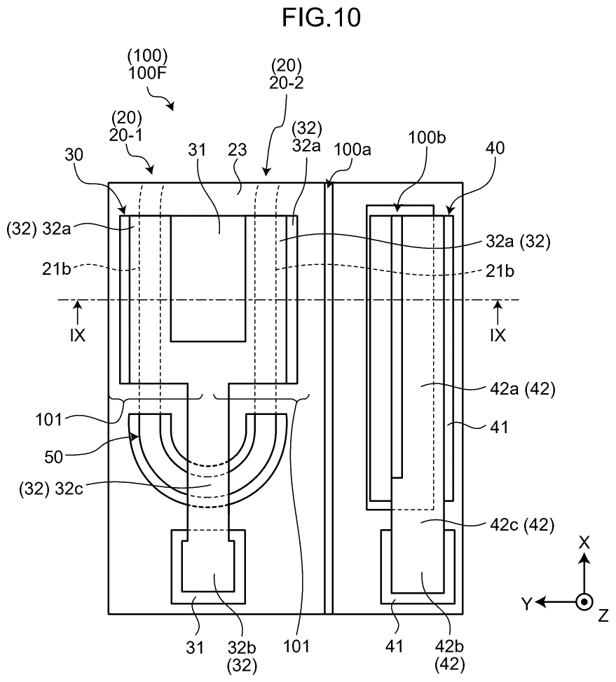

FIG. 9 is a cross-sectional view of a semiconductor optical device 100F (100) according to a sixth embodiment. FIG. 10 is a planar view of the semiconductor optical device 100F (100). FIG. 9 is an IX-IX cross-sectional view of FIG. 10. The semiconductor optical device 100F according to the sixth embodiment includes the two function units 101 and the folded waveguide structure 50 in an identical manner to the semiconductor optical device 100C according to the third embodiment, and operates in an identical manner to the semiconductor optical device 100C. However, in the sixth embodiment, an electrode 40F (40) that is an N-side electrode has a different configuration than the configuration according to the first to fifth embodiments described above.

More particularly, in the semiconductor optical device 100F, on the opposite side of the two function units 101 across the slit 100a, a depressed portion 100b is formed that is depressed in the opposite direction to the Z direction up to the substrate 10. The electrode 40F is disposed to run along a bottom surface 100b1 and a side surface 100b2 of the depressed portion 100b.

In an identical manner to the electrodes 30, the electrode 40F too includes a first layer 40a and a second layer 40b that is layered on the first layer 40a. As a result, a third portion 41 is formed that is made of only the first layer 40a, and a fourth portion 42 is formed that is made of the first layer 40a and the second layer 40b and that has a greater thickness than the thickness of the third portion 41. Meanwhile, on the insulation layer 23 that covers the depressed portion 100b, an opening 23b is formed at the position overlapping with the bottom surface 100b1. Thus, the first layer 40a makes contact with the substrate 10 via the opening 23b.

As illustrated in FIG. 10, the fourth portion 42 of the electrode 40F includes an action portion 42a, a pad portion 42b, and an extended portion 42c. The action portion 42a makes contact with the substrate 10 via the bottom surface 100b1 of the depressed portion 100b, and supplies an electrode to the substrate 10. The pad portion 42b is separated from the action portion in the opposite direction to the X direction. To the pad portion 42b is bonded a power supply member such as a bonding wire. The extended portion 42c extends in the X direction in between the action portion 42a and the pad portion 42b.

In the electrode 40F, the fourth portion 42 extends in the X direction for a longer distance than the third portion 41. With such a configuration too, in an identical manner to the first embodiment, while ensuring the required electrical conductivity and the required thermal dissipation in the electrode 40F, it becomes possible to further reduce the deformation in the second deformation mode in which the position of each layer in the Z direction goes on changing toward the Y direction. Hence, it becomes possible to hold down the change in the relative positions of the core layers 21b. In turn, it becomes possible to hold down the decline in the efficiency of optical coupling between the core layers 21b and the waveguides corresponding to the core layers 21b.

As illustrated in FIGS. 9 and 10, in the sixth embodiment, the level difference of the depressed portion 100b is crossed by the fourth portion 42 that has a greater thickness than the thickness of the third portion 41. With such a configuration, it becomes possible to prevent the disconnection of the electrode 40 at the crossing position, and to hold down an increase in the electrical resistance.

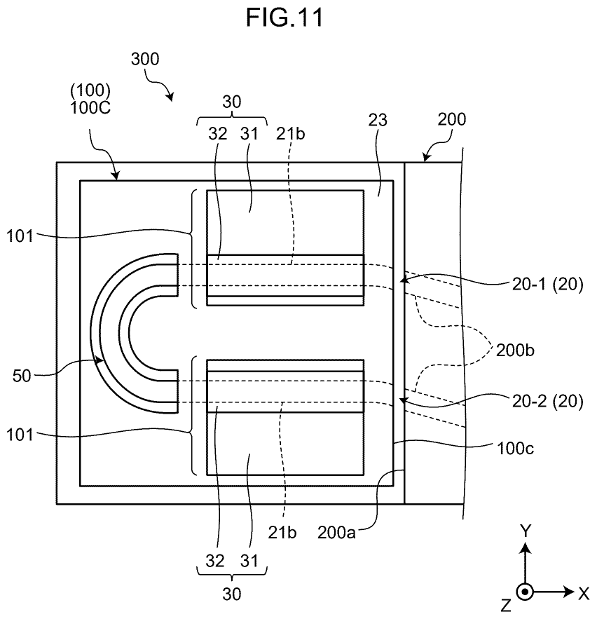

FIG. 11 is a planar view of an optical integrated device 300 according to a seventh embodiment. The optical integrated device 300 includes the semiconductor optical device 100C (100) according to the third embodiment and includes an optical function device 200. The optical function device 200 can also be referred to as a silicon platform.

An end surface 100c of the semiconductor optical device 100 in the X direction faces an end surface 200a of the optical function device 200 in the opposite direction to the X direction. The semiconductor optical device 100C has the configuration explained in the third embodiment. Hence, in the semiconductor optical device 100C (100), in an identical manner to the third and first embodiments, for example, it becomes possible to hold down thermal deformation and at the same time to hold down an increase in the electrical resistance in the electrodes 30 and to hold down a decline in thermal dissipation attributed to the electrodes 30. Hence, in the semiconductor optical device 100C (100) that includes the optical integrated device 300, the positioning of the end portions of the two core layers 21b on the end surface 100c in the X direction and the positioning of the end portions of core layers 200b (waveguides) at two places on the end surface 200a in the X direction can be performed in a more accurate manner. Hence, for example, it becomes possible to further reduce the coupling loss between the semiconductor optical device 100 and the optical function device 200. Meanwhile, the constituent material of the optical function device 200 is not limited to silicon, and it is possible to use some other semiconductor or glass.

While certain embodiments and modification examples have been described, these embodiments and modification examples have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure. Moreover, regarding the constituent elements, the specifications about the configurations and the shapes (structure, type, direction, shape, size, length, width, thickness, height, number, arrangement, position, material, etc.) can be suitably modified.

According to the present disclosure, it becomes possible to obtain a semiconductor optical device and an optical integrated device in a new and improved form.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor optical device comprising:
a substrate expanding while intersecting with a first direction;
a plurality of waveguide structures each of which includes a first cladding layer, a core layer, and a second cladding layer that are layered in the first direction, the plurality of waveguide structures extending in a second direction that intersects with the first direction and guiding lights in the second direction or opposite direction to the second direction, and being disposed away from each other in a third direction that intersects with the first direction and the second direction; and
a first electrode disposed on an opposite side of the substrate with respect to the waveguide structures, and including a first portion and a second portion having a thickness thicker than a thickness of the first portion in the first direction.

2. The semiconductor optical device according to claim 1, wherein the first electrode extends in the second direction across a first width and has the portion which at least partially extends in the second direction across a second width smaller than the first width.

3. The semiconductor optical device according to claim 2, wherein the first electrode has the first portion and the second portion at least partially arranged in the third direction.

4. The semiconductor optical device according to claim 2, wherein the second portion which at least partially extends in the second direction across the second width at a position aligned with the core layer in the first direction.

5. The semiconductor optical device according to claim 2, wherein the second portion at least partially extends in the second direction across the second width at a position misaligned in the third direction or in an opposite direction to the third direction with respect to a center of the first electrode in the third direction.

6. The semiconductor optical device according to claim 2, wherein the second portion extends in the second direction for a longer distance than the first portion.

7. The semiconductor optical device according to claim 1, wherein the first electrode includes:
a first layer constituting the first portion and some portion of the second portion; and
a second layer that constitutes such portion of the second portion which is on an opposite side of the waveguide structure with respect to the first layer.

8. The semiconductor optical device according to claim 1, wherein the waveguide structure constitutes an active waveguide.

9. The semiconductor optical device according to claim 1, wherein the waveguide structure includes two waveguide structures that are optically connected via a folded waveguide structure.

10. The semiconductor optical device according to claim 9, wherein the folded waveguide structure constitutes a passive waveguide.

11. The semiconductor optical device according to claim 9, further comprising a plurality of waveguide structure assemblies each of which includes the folded waveguide structure and includes two waveguide structures optically connected via the folded waveguide structure.

12. The semiconductor optical device according to claim 1, wherein the waveguide structure includes two waveguide structures that are arranged in the third direction via a slit extending in the second direction.

13. The semiconductor optical device according to claim 1, further comprising:
a depressed portion depressed in opposite direction to the first direction, the depressed portion being formed up to the substrate; and
a second electrode at least partially disposed inside the depressed portion.

14. The semiconductor optical device according to claim 13, wherein the second electrode includes a third portion and a fourth portion having a thickness thicker than a thickness of the third portion.

15. The semiconductor optical device according to claim 14, wherein the fourth portion includes an extended portion extending in the first direction along a side surface of the fourth portion.

16. The semiconductor optical device according to claim 1, further comprising a semiconductor optical amplifier including the waveguide structures and a pair of electrodes disposed in a corresponding manner to the waveguide structures.

17. The semiconductor optical device according to claim 1, further comprising a semiconductor light-emitting device including the waveguide structures and a pair of electrodes disposed in a corresponding manner to the waveguide structures.

18. An optical integrated device comprising, in an integrated manner:
the semiconductor optical device according to claim 1; and
an optical function device including a waveguide which is optically connected to the waveguide structures of the semiconductor optical device.
